(19) United States
(12) Patent Application Publication
(10) Pub. No.: US 2025/0056856 A1
(43) Pub. Date: Feb. 13, 2025

(54) SILICON CARBIDE SUBSTRATE, METHOD OF MANUFACTURING SILICON CARBIDE SEMICONDUCTOR DEVICE, AND METHOD OF MANUFACTURING SILICON CARBIDE SUBSTRATE

(71) Applicant: SUMITOMO ELECTRIC INDUSTRIES, LTD., Osaka (JP)

(72) Inventors: Naoki KAJI, Osaka (JP); Shunsaku UETA, Osaka (JP)

(73) Assignee: SUMITOMO ELECTRIC INDUSTRIES, LTD., Osaka (JP)

(21) Appl. No.: 18/719,575

(22) PCT Filed: Sep. 15, 2022
(86) PCT No.: PCT/JP2022/034585

§ 371 Date: Jun. 13, 2024

(30) Foreign Application Priority Data
Dec. 20, 2021 (JP) 2021-205778

(51) Int. Cl. H01L 29/16; H01L 21/02; H01L 29/66

(52) U.S. Cl. CPC H01L 29/1608; H01L 21/02378; H01L 29/66068

(57) ABSTRACT

A silicon carbide substrate has a main surface. The main surface is constituted of an outer peripheral region and a central region. The outer peripheral region is a region within 5 mm from an outer edge of the main surface. The central region is surrounded by the outer peripheral region. A standard deviation of lifetimes of minority carriers in the central region is 0.7 ns or less. A standard deviation of lifetimes of minority carriers in the central region before a process of heating to a temperature 1600-° C. to 1900° C. is performed is defined as a first standard deviation. A standard deviation of lifetimes of minority carriers in the central region after the process is performed is defined as a second standard deviation. A value obtained by subtracting the first standard deviation from the second standard deviation is 10% or less of the first standard deviation.

### TECHNICAL FIELD

The present disclosure relates to a silicon carbide substrate, a method of manufacturing a silicon carbide semiconductor device, and a method of manufacturing a silicon carbide substrate. This application claims priority based on Japanese Patent Application No. 2021-205778 filed on Dec. 20, 2021, and the entire contents of the Japanese patent application are incorporated herein by reference.

### BACKGROUND ART

Japanese National Patent Publication No. 2005-537657 (Patent literature 1) discloses a method of manufacturing a silicon carbide wafer having long lifetime of minority carriers.

### CITATION LIST

### Patent Literature

Patent literature 1: Japanese National Patent Publication No. 2005-537657

### SUMMARY OF INVENTION

A silicon carbide substrate according to the present disclosure includes a main surface. The main surface is constituted of an outer peripheral region and a central region. The outer peripheral region is a region within 5 mm from an outer edge of the main surface. The central region is surrounded by the outer peripheral region. A standard deviation of lifetimes of minority carriers in the central region is 0.7 ns or less. A standard deviation of lifetimes of the minority carriers in the central region before a process of heating to a temperature of 1600° C. to 1900° C. is performed is defined as a first standard deviation. A standard deviation of lifetimes of the minority carriers in the central region after the process is performed is defined as a second standard deviation. A value obtained by subtracting the first standard deviation from the second standard deviation is 10% or less of the first standard deviation.

### BRIEF DESCRIPTION OF THE DRAWINGS

FIG. 1 is a schematic plan view showing a configuration of a silicon carbide substrate according to the embodiment.

FIG. 2 is a schematic cross-sectional view taken along line II-II of FIG. 1.

FIG. 3 is a schematic view showing a crystal structure of a silicon carbide substrate according to the embodiment.

FIG. 4 is a schematic plan view showing measurement positions of lifetimes of minority carriers.

FIG. 5 is a schematic partial cross-sectional view of a manufacturing apparatus showing a configuration of a manufacturing apparatus for a silicon carbide substrate according to the embodiment.

FIG. 6 is a flow chart schematically showing a method of manufacturing a silicon carbide substrate according to the embodiment.

FIG. 7 is a schematic partial cross-sectional view of a manufacturing apparatus for a silicon carbide substrate showing a growing step according to the embodiment.

FIG. 8 is a schematic partial cross-sectional view of a manufacturing apparatus for a silicon carbide substrate showing a heat treatment step according to the embodiment.

FIG. 9 is a flow chart schematically showing a method of manufacturing a silicon carbide semiconductor device according to the embodiment.

FIG. 10 is a schematic cross-sectional view showing a step of forming a silicon carbide epitaxial layer on a silicon carbide substrate according to the embodiment.

FIG. 11 is a schematic cross-sectional view showing a step of forming a body region according to the embodiment.

FIG. 12 is a schematic cross-sectional view showing a step of forming a source region according to the embodiment.

FIG. 13 is a schematic cross-sectional view showing a step of forming a trench in a third main surface of a silicon carbide epitaxial layer according to the embodiment.

FIG. 14 is a schematic cross-sectional view showing a step of forming a gate insulating film according to the embodiment.

FIG. 15 is a schematic cross-sectional view showing a step of forming a gate electrode and an interlayer insulating film according to the embodiment.

FIG. 16 is a schematic cross-sectional view showing a configuration of a silicon carbide semiconductor device according to the embodiment.

### DETAILED DESCRIPTION

### Problems to be Solved by Present Disclosure

An object of the present disclosure is to provide a silicon carbide substrate, a method of manufacturing a silicon carbide semiconductor device, and a method of manufacturing a silicon carbide substrate, which can improve the yield of a silicon carbide semiconductor device.

### Advantageous Effect of the Present Disclosure

According to the present disclosure, it is possible to provide a silicon carbide substrate, a method of manufacturing a silicon carbide semiconductor device, and a method of manufacturing a silicon carbide substrate, which can improve the yield of a silicon carbide semiconductor device.

### DESCRIPTION OF EMBODIMENTS

First, embodiments of the present disclosure will be listed and described.

(1) A silicon carbide substrate according to the present disclosure includes a main surface. The main surface is constituted of an outer peripheral region and a central region. The outer peripheral region is a region within 5 mm from an outer edge of the main surface. The central region is surrounded by the outer peripheral region. A standard deviation of lifetimes of minority carriers in the central region is 0.7 ns or less. A standard deviation of lifetimes of the minority carriers in the central region before a process of heating to a temperature of 1600° C. to 1900° C. is performed is defined as a first standard deviation. A standard deviation of lifetimes of the minority carriers in the central region after the process is performed is defined as a second standard deviation. A value obtained by subtracting the first standard deviation from the second standard deviation is 10% or less of the first standard deviation.

(2) In the silicon carbide substrate according to (1) above, a concentration of majority carriers in the central region may be 1×10¹⁷ cm⁻³ or more.

(3) In the silicon carbide substrate according to (2) above, the majority carriers may be n-type carriers.

(4) In the silicon carbide substrate according to any one of (1) to (3) above, the value obtained by subtracting the first standard deviation from the second standard deviation may be 5% or less of the first standard deviation.

(5) In the silicon carbide substrate according to any one of (1) to (4) above, an average value of the lifetimes of the minority carriers in the central region may be 200 ns or less.

(6) In the silicon carbide substrate according to any one of (1) to (5) above, the main surface may have a diameter of 100 mm or more.

(7) In the silicon carbide substrate according to any one of (1) to (6) above, the main surface may be inclined at an off-angle in an off-direction relative to a {0001}plane. The off-angle may be more than 0° and 8° or less.

(8) A method of manufacturing a silicon carbide semiconductor device according to the present disclosure includes the following steps. The silicon carbide substrate according to any one of (1) to (7) above is prepared. The silicon carbide substrate is processed.

(9) A method of manufacturing a silicon carbide substrate according to the present disclosure includes the following steps. A silicon carbide crystal is grown on a seed crystal by sublimating source material powder in which carbon powder is added to silicon carbide powder. Heat treatment is performed on the grown silicon carbide crystal. In the performing heat treatment, a heat treatment temperature is 1900° C. to 2100° C., and a heat treatment time is 20 hours or more.

### Detailed Description of Embodiments

Hereinafter, embodiments of the present disclosure (hereinafter, also referred to as the embodiments) will be described in detail with reference to the drawings. In the drawings, the same or corresponding portions are denoted by the same reference characters, and description thereof will not be repeated. Regarding crystallographic indications in the present specification, an individual orientation is represented by [ ], a group orientation is represented by < >, an individual plane is represented by ( ), and a group plane is represented by { }.

Generally, a negative index is supposed to be crystallographically indicated by putting “—” (bar) above a numeral but is indicated by putting the negative sign before the numeral in the present specification.

### (Silicon Carbide Single Crystal)

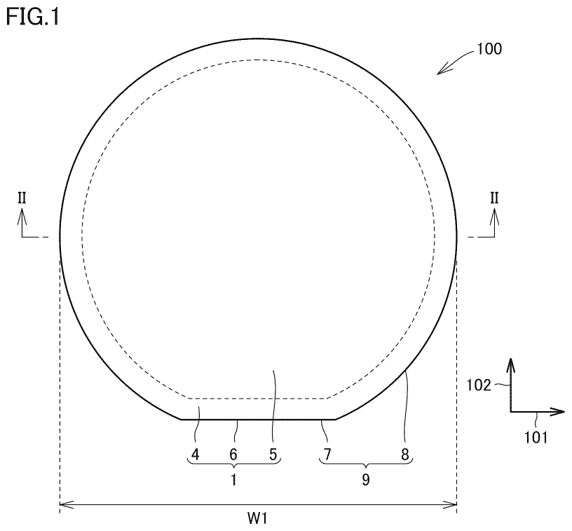

First, a configuration of a silicon carbide substrate 100 according to the embodiment will be described. FIG. 1 is a schematic plan view showing a configuration of silicon carbide substrate 100 according to the embodiment.

As shown in FIG. 1, silicon carbide substrate 100 according to the embodiment has a first main surface 1 and a first outer peripheral side surface 9. First main surface 1 extends along each of first direction 101 and second direction 102. First direction 101 is not particularly limited, and is, for example, a <11-20> direction. Second direction 102 is not particularly limited, and is, for example, a <1-100> direction. First outer peripheral side surface 9 is contiguous to first main surface 1. Silicon carbide substrate 100 contains an n-type impurity such as nitrogen. Silicon carbide substrate 100 is made of, for example, hexagonal silicon carbide. A polytype of hexagonal silicon carbide is, for example, 4H.

Silicon carbide substrate 100 is used, for example, as a substrate of a semiconductor device such as a Schottky barrier diode (SBD) or a metal oxide semiconductor field effect transistor (MOSFET).

As shown in FIG. 1, a ridge line between first main surface 1 and first outer peripheral side surface 9 forms an outer edge 6 of first main surface 1. First main surface 1 is constituted of an outer peripheral region 4 and a central region 5. Outer peripheral region 4 is a region within 5 mm from outer edge 6 of first main surface 1. In other words, outer peripheral region 4 is a region within 5 mm from first outer peripheral side surface 9 when viewed in a direction perpendicular to first main surface 1. Central region 5 is contiguous to outer peripheral region 4. Central region 5 is surrounded by outer peripheral region 4. From another viewpoint, central region 5 is a region in which a distance from outer edge 6 of first main surface 1 is larger than 5 mm.

As shown in FIG. 1, first outer peripheral side surface 9 has an orientation flat portion 7 and an arc-shaped portion 8. Arc-shaped portion 8 is contiguous to orientation flat portion 7. As shown in FIG. 1, when viewed from the direction perpendicular to first main surface 1, orientation flat portion 7 may extend along first direction 101.

A diameter (first diameter W1) of first main surface 1 is, for example, 150 mm. First diameter W1 is 100 mm or more. The lower limit of first diameter W1 is not particularly limited, and may be 150 mm or more, or 200 mm or more. The upper limit of first diameter W1 is not particularly limited, and may be, for example, 300 mm or less. When viewed in the direction perpendicular to first main surface 1, first diameter W1 is the longest straight line distance between two different points on first outer peripheral side surface 9.

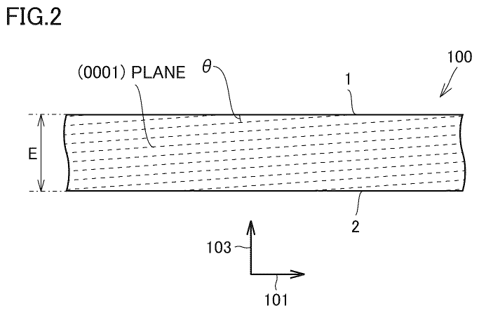

FIG. 2 is a schematic cross-sectional view taken along line II-II in FIG. 1. The cross-section shown in FIG. 2 is perpendicular to first main surface 1 and parallel to first direction 101. As shown in FIG. 2, silicon carbide substrate 100 according to the embodiment further includes a second main surface 2. Second main surface 2 is opposite to first main surface 1. A thickness E of silicon carbide substrate 100 is, for example, 300 μm to 700 μm. A third direction 103 is a direction perpendicular to each of first direction 101 and second direction 102. A thickness direction of silicon carbide substrate 100 is the same as third direction 103.

First main surface 1 is a {0001}plane or a plane inclined in an off-direction relative to the {0001}plane. Specifically, first main surface 1 may be a (0001) plane or a plane inclined in the off-direction relative to the (0001) plane. The off-direction is, for example, first direction 101. An incline angle (hereinafter, referred to as off-angle θ) of first main surface 1 relative to the {0001}plane is, for example, more than 0° and 8° or less. The upper limit of off-angle θ is not particularly limited, and may be, for example, 6° or less, or 4° or less. The lower limit of off-angle θ is not particularly limited, and may be, for example, 1° or more, or 2° or more. Off-angle θ may be 0°.

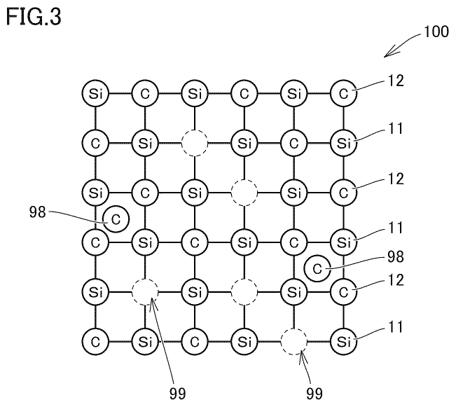

FIG. 3 is a schematic view showing a crystal structure of silicon carbide substrate 100 according to the embodiment. As shown in FIG. 3, silicon carbide substrate 100 is mainly composed of silicon atoms 11, carbon atoms 12, and interstitial carbons 98. Carbon atoms 12 are bonded to silicon atoms 11. Silicon atoms 11 and carbon atoms 12 form a crystal lattice. Interstitial carbons 98 are located in gaps of the crystal lattice. In the crystal lattice, carbon vacancies 99 are formed. Carbon vacancies 99 are formed by lack of carbon atoms 12 from the crystal lattice. In silicon carbide substrate 100, a density of interstitial carbons 98 is smaller than a density of carbon vacancies 99. In silicon carbide substrate 100, the density of interstitial carbons 98 may be, for example, 1/100 or less of the density of carbon vacancies 99. The density of carbon vacancies 99 in silicon carbide substrate 100 may be, for example, 1×10¹⁶ atoms/cm³ or less.

### (Concentration of Majority Carriers of Silicon Carbide Substrate)

Silicon carbide substrate 100 according to the embodiment has, for example, conductivity. To be specific, a concentration of majority carriers in central region 5 of silicon carbide substrate 100 is, for example, 1×10¹⁷ cm⁻³ or more. Hereinafter, the concentration of the majority carriers is also simply referred to as a carrier concentration. The lower limit of the carrier concentration is not particularly limited, and may be 1×10¹⁸ cm⁻³ or more, or 1×10¹⁹ cm⁻³ or more. The majority carriers are, for example, n-type carriers. Specifically, the majority carriers are for example, electrons. Silicon carbide substrate 100 contains, for example, nitrogen (N) as an n-type impurity that generates electrons. The carrier concentration can be measured, for example, by Hall effect measurement.

The configuration of silicon carbide substrate 100 according to the embodiment is not limited to the above-described configuration. Specifically, silicon carbide substrate 100 may have a semi-insulating property. More specifically, an electrical resistivity of silicon carbide substrate 100 may be 1×10⁵ Ωcm or more. The concentration of majority carriers in central region 5 of silicon carbide substrate 100 may be less than 1×10¹⁷ cm⁻³, for example. The majority carriers may be p-type carriers. Specifically, the majority carriers may be vacancies. Silicon carbide substrate 100 may contain, for example, aluminum (Al) or boron (B) as a p-type impurity that generates vacancies.

### (Lifetimes of Minority Carriers of Silicon Carbide Substrate)

Next, a method of measuring lifetimes of minority carriers in silicon carbide substrate 100 will be described. Hereinafter, the lifetime of each of the minority carriers is also simply referred to as a carrier lifetime. The carrier lifetime is measured by, for example, a Microwave PhotoConductivity Decay (μ-PCD) method. Specifically, a sample is irradiated with a pulse laser to generate excess carriers inside the sample. This changes a resistivity of the sample. Thereafter, the excess carriers are recombined, and the resistivity of the sample returns to the state before the irradiation of the pulse laser. Thus, by measuring the time change of the resistivity of the sample, the time until the excess carriers recombine can be measured.

The resistivity of the sample is measured by measuring a reflectance of microwaves at an irradiation position of the pulse laser. The time in which the reflectance of the microwave is decayed from a peak value to 1/e is defined as a carrier lifetime. Note that e is the Napier's constant. In the μ-PCD method, for example, LTA-2200EP, which is a lifetime measuring apparatus manufactured by Kobelco Research Institute, can be used. Measurement conditions in the μ-PCD method are, for example, a microwave probe frequency of 26 GHz. A laser is a YLF laser. A dopant of the YLF laser is neodymium. A pulse width of the laser is 5 ns. A laser wave length is 349 nm (third harmonic). A temperature is room temperature.

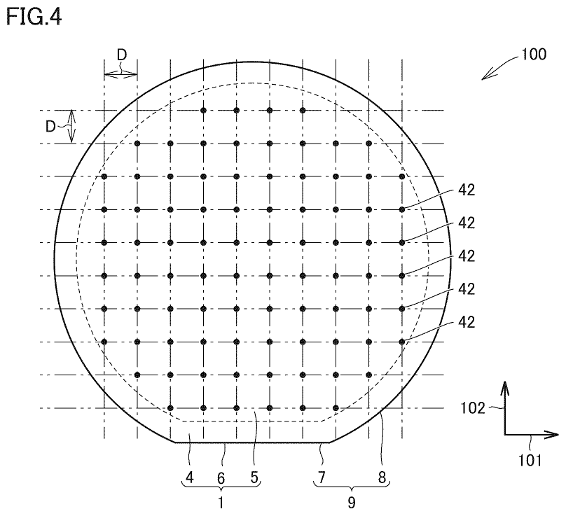

FIG. 4 is a schematic plan view showing measurement positions of lifetimes of minority carriers. In central region 5 of first main surface 1, the carrier lifetimes are measured. In other words, the carrier lifetimes in outer peripheral region 4 are not measured. As shown in FIG. 4, measurement points 42 are located on central region 5 of first main surface 1. Measurement points 42 are positioned in a lattice shape. The lattice is formed, for example, with first direction 101 as a horizontal direction and second direction 102 as a vertical direction. A distance D between adjacent measurement points 42 is, for example, 2 mm. The number of measurement points 42 is, for example, 4200. A standard deviation of the carrier lifetimes in central region 5 of silicon carbide substrate 100 is measured from the carrier lifetimes at each of measurement points 42.

In the present specification, the standard deviation of the carrier lifetimes is distinguished for each before and after a process of heating silicon carbide substrate 100 to a temperature of 1600° C. to 1900° C. is performed. Specifically, the standard deviation of the carrier lifetimes before the process of heating is performed is referred to as a first standard deviation. The standard deviation of the carrier lifetimes after the process of heating has been performed is referred to as a second standard deviation. Usually, the second standard deviation is larger than the first standard deviation.

The first standard deviation is, for example, 0.6 ns. The first standard deviation is 0.7 ns or less. The upper limit of the first standard deviation is not particularly limited, and may be, for example, 0.65 ns or less, or 0.62 ns or less. The lower limit of the first standard deviation is not particularly limited, and may be, for example, 0.2 ns or more, or 0.3 ns or more.

A value obtained by subtracting the first standard deviation from the second standard deviation is 10% or less of the first standard deviation. In other words, the standard deviation of the carrier lifetimes before and after the process of heating is performed has a change rate of 10% or less. The value obtained by subtracting the first standard deviation from the second standard deviation may be, for example, 5% or less of the first standard deviation, or 3% or less of the first standard deviation. The lower limit of the value obtained by subtracting the first standard deviation from the second standard deviation is not particularly limited, and may be, for example, 0.5% or more of the first standard deviation, or 1% or more of the first standard deviation.

An average value of the carrier lifetimes at each of measurement points 42 is set to an average value of the carrier lifetimes in central region 5 of silicon carbide substrate 100 (hereinafter, simply referred to as an average value of the carrier lifetimes). The average value of the carrier lifetimes is, for example, 150 ns. The average value of the carrier lifetimes may be 200 ns or less. The upper limit of the average value of the carrier lifetimes is not particularly limited, and may be, for example, 180 ns or less, or 160 ns or less. The lower limit of the average value of the carrier lifetimes is not particularly limited, and may be, for example, 20 ns or more, or 30 ns or more.

### (Manufacturing Apparatus for Silicon Carbide Substrate)

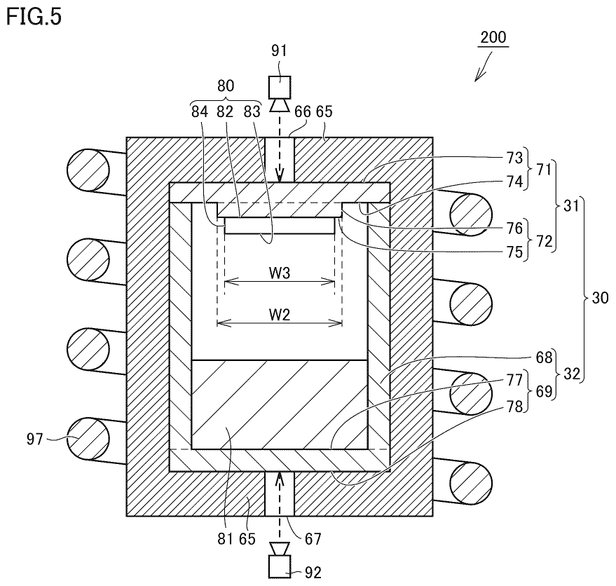

Next, a manufacturing apparatus for silicon carbide substrate 100 according to the embodiment will be described. FIG. 5 is a schematic partial cross-sectional view of a manufacturing apparatus showing a configuration of a manufacturing apparatus for silicon carbide substrate 100 according to the embodiment. As shown in FIG. 5, a manufacturing apparatus 200 for silicon carbide substrate 100 includes a crucible 30, a heat insulating member 65, an induction heating coil 97, a first radiation thermometer 91, and a second radiation thermometer 92. Heat insulating member 65 covers crucible 30. Induction heating coil 97 is wound around an outer periphery of heat insulating member 65. Crucible 30 is heated by supplying electric power to induction heating coil 97. Each of first radiation thermometer 91 and second radiation thermometer 92 measures the temperature of crucible 30.

Crucible 30 includes a lid portion 31 and a container portion 32. Lid portion 31 is located above container portion 32. Lid portion 31 is detachable from container portion 32. Lid portion 31 includes a base portion 71 and a holding portion 72. Base portion 71 has a top surface 73 and an inner surface 74. Inner surface 74 is opposite to top surface 73. Holding portion 72 is contiguous to base portion 71. Holding portion 72 is disc-shaped. Holding portion 72 has a holding surface 75 and a second outer peripheral side surface 76. Holding surface 75 is opposite to top surface 73. Second outer peripheral side surface 76 is contiguous to each of inner surface 74 and holding surface 75.

Container portion 32 includes a tubular portion 68 and a bottom portion 69. Tubular portion 68 is in contact with lid portion 31 at inner surface 74. Bottom portion 69 is contiguous to tubular portion 68. Bottom portion 69 has a mounting surface 77 and a bottom surface 78. Mounting surface 77 faces holding surface 75. Bottom surface 78 is opposite to mounting surface 77.

### (Method of Manufacturing Silicon Carbide Substrate)

Next, a method of manufacturing silicon carbide substrate 100 according to the embodiment will be described. As shown in FIG. 5, source material powder 81 is disposed on mounting surface 77 of container portion 32 of crucible 30. Source material powder 81 is a mixed powder in which carbon powder is added to silicon carbide powder. A weight ratio of the carbon powder to the carbon silicon powder is, for example, 5% or less.

A seed crystal 80 is attached to holding surface 75 of lid portion 31 by using, for example, an adhesive (not shown). Seed crystal 80 is disc-shaped. Seed crystal 80 has an attachment surface 82, a growth surface 83, and a third outer peripheral side surface 84. Attachment surface 82 is in contact with holding surface 75 of lid portion 31. Growth surface 83 is opposite to attachment surface 82. Growth surface 83 faces source material powder 81. Third outer peripheral side surface 84 is contiguous to each of attachment surface 82 and growth surface 83.

A diameter (second diameter W2) of second outer peripheral side surface 76 of holding portion 72 is larger than a diameter (third diameter W3) of third outer peripheral side surface 84 of seed crystal 80. A value obtained by dividing second diameter W2 by third diameter W3 is, for example, 1.02 or more. From another viewpoint, third outer peripheral side surface 84 is positioned inside second outer peripheral side surface 76 in a radial direction of second outer peripheral side surface 76. The central axis of third outer peripheral side surface 84 of seed crystal 80 may be positioned on the same line as the central axis of second outer peripheral side surface 76 of holding portion 72.

Seed crystal 80 is made of, for example, hexagonal silicon carbide. A polytype of hexagonal silicon carbide is, for example, 4H. A diameter of growth surface 83 is, for example, 150 mm. The diameter of growth surface 83 is, for example, 100 mm or more. Growth surface 83 is a {0001}plane or a plane inclined at an off angle of 8° or less relative to the {0001}plane, for example.

First radiation thermometer 91 measures a temperature of seed crystal 80 by measuring a temperature of top surface 73 of crucible 30 through a first through hole 66 provided in heat insulating member 65. Second radiation thermometer 92 measures a temperature of source material powder 81 by measuring a temperature of bottom surface 78 of crucible 30 through a second through hole 67 provided in heat insulating member 65. As described above, seed crystal 80 and source material powder 81 are prepared.

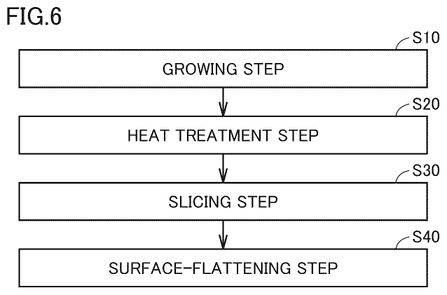

FIG. 6 is a flow chart schematically showing a method of manufacturing silicon carbide substrate 100 according to the embodiment. As shown in FIG. 6, the method of manufacturing silicon carbide substrate 100 according to the embodiment mainly includes a growing step (S10), a heat treatment step (S20), a slicing step (S30), and a surface-flattening step (S40).

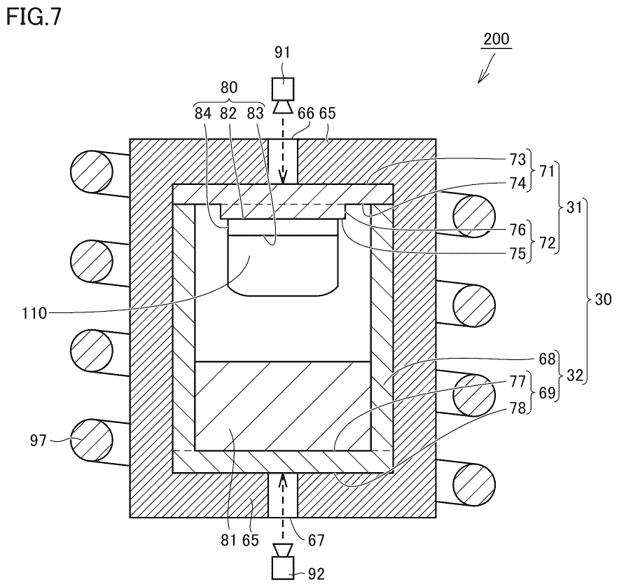

First, the growing step (S10) is performed. FIG. 7 is a schematic partial cross-sectional view of manufacturing apparatus 200 for silicon carbide substrate 100, showing the growing step (S10) according to the embodiment. In the growing step (S10), the inside of crucible 30 is filled with an inert gas atmosphere such as argon. Nitrogen gas is introduced into crucible 30.

Electric power is supplied to induction heating coil 97 from a power source (not shown). As a result, crucible 30 is heated. Each of source material powder 81 and seed crystal 80 is heated by heat transfer from crucible 30. Source material powder 81 is heated so that the temperature of source material powder 81 is higher than the temperature of seed crystal 80. As a result, source material powder 81 is sublimated, and silicon carbide gas is generated. The silicon carbide gas is recrystallized on growth surface 83 of seed crystal 80. As shown in FIG. 7, a silicon carbide crystal 110 is grown as a single crystal on growth surface 83 of seed crystal 80. Nitrogen atoms are incorporated inside silicon carbide crystal 110. Thereafter, silicon carbide crystal 110 is cooled to room temperature.

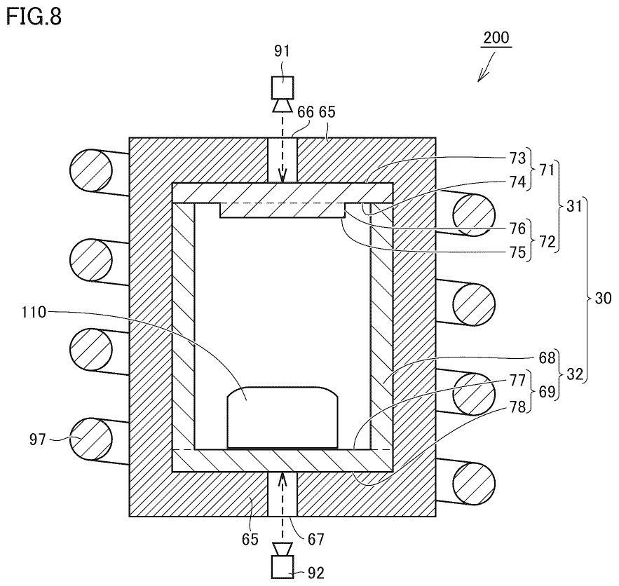

Next, the heat treatment step (S20) is performed. FIG. 8 is a schematic partial cross-sectional view of manufacturing apparatus 200 for silicon carbide substrate 100 showing the heat treatment step (S20) according to the embodiment. In the heat treatment step (S20), manufacturing apparatus 200 for a silicon carbide substrate is prepared. Silicon carbide crystal 110 is disposed on mounting surface 77 of container portion 32. Silicon carbide crystal 110 is heated to a heat treatment temperature. The heat treatment temperature is, for example, 2000° C. The heat treatment temperature is, for example, 1900° C. to 2100° C. The upper limit of the heat treatment temperature is not particularly limited, and may be, for example, 2050° C. or less. The lower limit of the heat treatment temperature is not particularly limited, and may be, for example, 1950° C. or more.

Silicon carbide crystal 110 is heat-treated at the heat treatment temperature for, for example, 20 hours or more. As silicon carbide crystal 110 is heated to the heat treatment temperature, interstitial carbons 98 and carbon vacancies 99 are generated (see FIG. 3). Some of interstitial carbons 98 fly out of a surface of silicon carbide crystal 110 to an outside of silicon carbide crystal 110. In other words, some of interstitial carbons 98 disappear inside silicon carbide crystal 110. Thus, the density of interstitial carbons 98 in silicon carbide crystal 110 is smaller than the density of carbon vacancies 99. From another viewpoint, by performing the heat treatment for a long time, carbon vacancies having a density determined by a thermal equilibrium state at the heat treatment temperature are generated. On the other hand, the interstitial carbon is in a state of a density lower than the density determined by the thermal equilibrium state of the heat treatment temperature.

By performing the heat treatment at a high temperature for a long time, silicon carbide crystal 110 is in a state of a high temperature and high temperature uniformity. Thus, in silicon carbide crystal 110, the density of interstitial carbons 98 can be significantly reduced while maintaining a state in which the densities of interstitial carbons 98 and carbon vacancies 99 are highly uniform.

In the heat treatment step (S20), crucible 30 is in an inert atmosphere such as argon. The pressure in crucible 30 is maintained at, for example, 80 kPa. After the heat treatment, silicon carbide crystal 110 is cooled to 1000° C. or less in, for example, 5 hours.

Interstitial carbons are easily diffused and free to migrate at high temperatures. Carbon vacancies are difficult to diffuse, are fixed, and are unable to migrate even at high temperatures. In general, interstitial carbons 98 and carbon vacancies 99 generated by heating recombine and annihilate as interstitial carbons 98 migrate to positions of carbon vacancies 99 during cooling. However, some of interstitial carbons 98 disappear inside silicon carbide crystal 110 by the heat treatment. Thus, recombination of interstitial carbons 98 and carbon vacancies 99 is suppressed. As a result, even when the temperature of silicon carbide crystal 110 is lowered, carbon vacancies 99 in silicon carbide crystal 110 are maintained in a state of high density and high uniformity of density.

Next, the slicing step (S30) is performed. In the slicing step (S30), silicon carbide crystal 110 is sliced. Specifically, silicon carbide crystal 110 is sliced along a plane perpendicular to the central axis of silicon carbide crystal 110 using, for example, a saw wire. Thus, silicon carbide wafers are obtained.

Next, the surface-flattening step (S40) is performed. In the surface-flattening step (S40), a surface of the silicon carbide wafer is flattened. Specifically, polishing such as mechanical polishing (MP) or chemical mechanical polishing (CMP) is performed on the surface of the silicon carbide wafer. Each surface of the silicon carbide wafer corresponds to either first main surface 1 or second main surface 2 of silicon carbide substrate 100.

As described above, silicon carbide substrate 100 is manufactured. In the method of manufacturing silicon carbide substrate 100, the slicing step (S30) may be performed before the heat treatment step (S20). To be specific, the heat treatment step (S20) may be performed on the silicon carbide wafer obtained by the slicing step (S30). Thereafter, the surface-flattening step (S40) is performed on the silicon carbide wafer, thereby manufacturing silicon carbide substrate 100.

### (Method of Manufacturing Silicon Carbide Semiconductor Device)

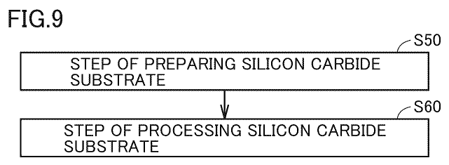

Next, a method of manufacturing the silicon carbide semiconductor device according to the embodiment will be described. FIG. 9 is a flow chart schematically showing a method of manufacturing a silicon carbide semiconductor device 400 according to the embodiment. As shown in FIG. 9, the method of manufacturing silicon carbide semiconductor device 400 according to the embodiment mainly includes a step of preparing a silicon carbide substrate (S50) and a step of processing the silicon carbide substrate (S60).

First, the step of preparing the silicon carbide substrate (S50) is performed. In the step of preparing the silicon carbide substrate (S50), silicon carbide substrate 100 according to the embodiment is prepared (see FIGS. 1 and 2).

Next, the step of processing the silicon carbide substrate (S60) is performed. The “processing” includes various kinds of processing such as formation of an epitaxial layer, ion implantation, heat treatment, etching, oxide film formation, electrode formation, and dicing. That is, the step of processing the silicon carbide substrate (S60) may include at least one of the following processes: formation of an epitaxial layer, ion implantation, heat treatment, etching, oxide film formation, electrode formation, and dicing. Specifically, first, the formation of a silicon carbide epitaxial layer is performed on the silicon carbide substrate.

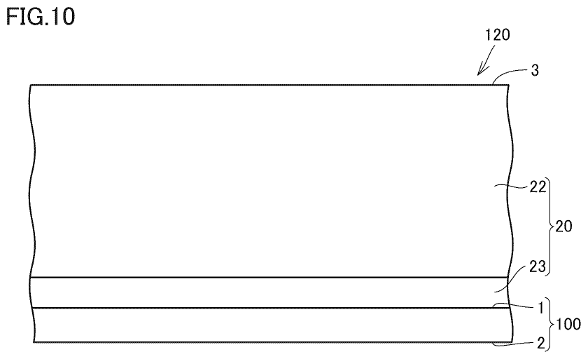

FIG. 10 is a schematic cross-sectional view showing a step of forming a silicon carbide epitaxial layer on silicon carbide substrate 100 according to the embodiment. Specifically, a silicon carbide epitaxial layer 20 is formed on first main surface 1 of silicon carbide substrate 100. In the step of forming the silicon carbide epitaxial layer, a growth temperature is, for example, 1600° C. to 1800° C. In other words, in the step of forming the silicon carbide epitaxial layer, silicon carbide substrate 100 is heated to a temperature of, for example, 1600° C. to 1800° C.

As shown in FIG. 10, silicon carbide epitaxial layer 20 may include a buffer layer 23 and a drift layer 22. Buffer layer 23 is in contact with silicon carbide substrate 100. Drift layer 22 is formed on buffer layer 23. Silicon carbide epitaxial layer 20 may be constituted only of drift layer 22. Drift layer 22 constitutes a third main surface 3 of silicon carbide epitaxial layer 20. Third main surface 3 is opposite to second main surface 2 of silicon carbide substrate 100. In this way, a silicon carbide epitaxial substrate 120 is manufactured.

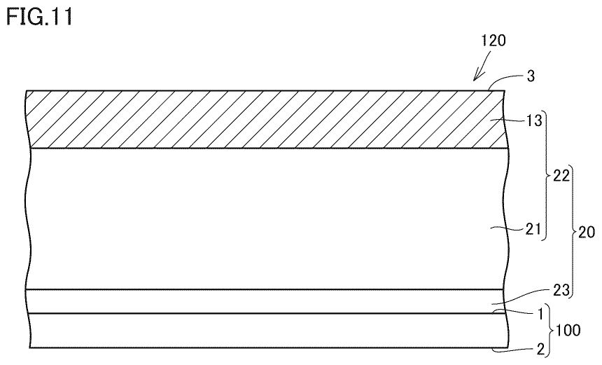

Next, ion implantation is performed into silicon carbide epitaxial layer 20. FIG. 11 is a schematic cross-sectional view showing a step of forming a body region according to the embodiment. Specifically, a p-type impurity such as aluminum is ion-implanted into third main surface 3 of silicon carbide epitaxial layer 20. Thus, a body region 13 having a p-type conductivity is formed. In drift layer 22, a part where body region 13 is not formed becomes a drift region 21. A thickness of body region 13 is, for example, 0.9 μm.

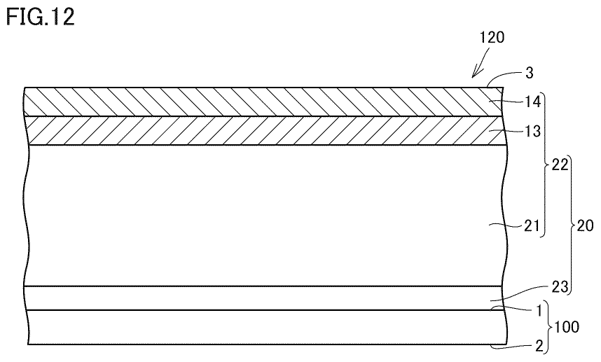

Next, a step of forming a source region is performed. FIG. 12 is a schematic cross-sectional view showing a step of forming a source region according to the embodiment. Specifically, an n-type impurity such as phosphorus is ion-implanted into body region 13. Thus, a source region 14 having an n-type conductivity is formed. A thickness of source region 14 is, for example, 0.4 μm. A concentration of the n-type impurity contained in source region 14 is higher than a concentration of the p-type impurity contained in body region 13.

Then, a p-type impurity such as aluminum is ion-implanted into source region 14, thereby forming a contact region 18. Contact region 18 is formed to pass through source region 14 and body region 13 and to be in contact with drift region 21. A concentration of the p-type impurity contained in contact region 18 is higher than the concentration of the n-type impurity contained in source region 14.

Next, activation annealing is performed to activate the ion-implanted impurities. The activation annealing is preferably performed at a temperature of 1500° C. to 1850° C., for example, about 1700° C. The activation annealing is performed for a period of about 30 minutes, for example. The activation annealing is preferably performed in an inert gas atmosphere, for example, an argon atmosphere.

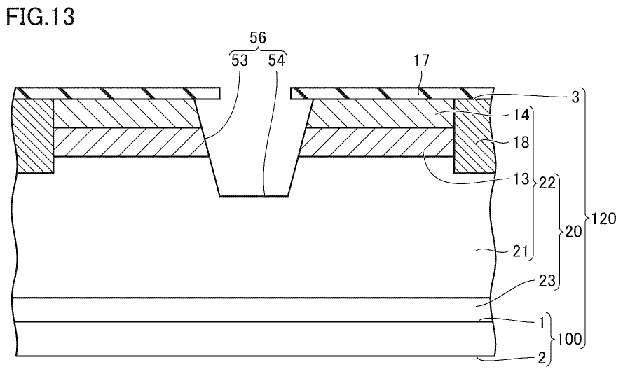

Next, a step of forming a trench in third main surface 3 of silicon carbide epitaxial layer 20 is performed. FIG. 13 is a schematic cross-sectional view showing a step of forming a trench in third main surface 3 of silicon carbide epitaxial layer 20 according to the embodiment. A mask 17 having an opening is formed on third main surface 3 constituted of source region 14 and contact region 18. Source region 14, body region 13, and a part of drift region 21 are removed by etching using mask 17. As an etching method, for example, reactive ion etching, particularly inductively coupled plasma reactive ion etching can be used. Specifically, for example, inductively coupled plasma reactive ion etching using sulfur hexafluoride (SF₆) or a mixed gas of SF₆ and oxygen (O₂) as a reactive gas may be used. By the etching, a recess is formed in third main surface 3.

Next, thermal etching is performed in the recess. The thermal etching can be performed by heating in an atmosphere containing a reactive gas having at least one or more kinds of halogen atoms, for example, in a state where mask 17 is formed on third main surface 3. At least one or more kinds of halogen atoms includes at least one of a chlorine (Cl) atom and a fluorine (F) atom. The atmosphere contains, for example, chloride (Cl₂), boron trichloride (BCl₃), SF₆ or tetrafluoromethane (CF₄). For example, the thermal etching is performed using a mixed gas of chlorine gas and oxygen gas as a reaction gas at a heat treatment temperature of, for example, 700° C. to 1000° C. The reaction gas may contain a carrier gas in addition to the chlorine gas and the oxygen gas described above. As the carrier gas, for example, nitrogen gas, argon gas, helium gas, or the like can be used.

As shown in FIG. 13, a trench 56 is formed in third main surface 3 by the thermal etching. Trench 56 is defined by side wall surfaces 53 and a bottom wall surface 54. Side wall surface 53 is constituted of source region 14, body region 13, and drift region 21. Bottom wall surface 54 is constituted of drift region 21. Next, mask 17 is removed from third main surface 3.

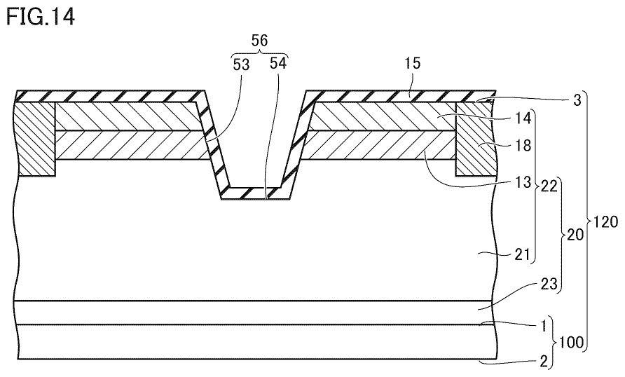

Next, a step of forming a gate insulating film is performed. FIG. 14 is a schematic cross-sectional view showing a step of forming a gate insulating film according to the embodiment. Specifically, silicon carbide epitaxial substrate 120 having trench 56 formed in third main surface 3 is heated in an atmosphere containing oxygen at a temperature of, for example, 1300° C. to 1400° C. Thus, a gate insulating film 15 which is in contact with drift region 21 on bottom wall surface 54, in contact with each of drift region 21, body region 13, and source region 14 on side wall surface 53, and in contact with each of source region 14 and contact region 18 on third main surface 3 is formed.

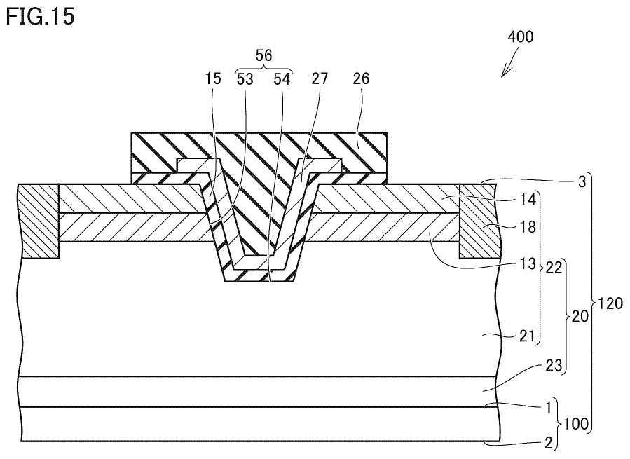

Next, a step of forming a gate electrode is performed. FIG. 15 is a schematic cross-sectional view showing a step of forming a gate electrode and an interlayer insulating film according to the embodiment. A gate electrode 27 is formed so as to be in contact with gate insulating film 15 inside trench 56. Gate electrode 27 is disposed inside trench 56 and is formed on gate insulating film 15 so as to face each of side wall surfaces 53 and bottom wall surface 54 of trench 56. Gate electrode 27 is formed by, for example, a low pressure chemical vapor deposition (LPCVD) method.

Next, an interlayer insulating film is formed. An interlayer insulating film 26 is formed to cover gate electrode 27 and to be in contact with gate insulating film 15. Interlayer insulating film 26 is formed by, for example, a chemical vapor deposition method. Interlayer insulating film 26 is made of a material containing silicon dioxide, for example. Next, interlayer insulating film 26 and gate insulating film 15 are partially etched so that an opening is formed on source region 14 and contact region 18. As a result, contact region 18 and source region 14 are exposed from gate insulating film 15.

Next, a step of forming a source electrode is performed. A source electrode 16 is formed so as to be in contact with each of source region 14 and contact region 18. Source electrode 16 is formed by, for example, a sputtering method. Source electrode 16 is made of a material containing titanium (Ti), aluminum (Al), and silicon (Si), for example.

Next, alloying annealing is performed. Specifically, source electrode 16 in contact with each of source region 14 and contact region 18 is held for about 5 minutes at a temperature of 900° C. to 1100° C., for example. Thus, at least a part of source electrode 16 is silicided. Thus, source electrode 16 in ohmic contact with source region 14 is formed. Preferably, source electrode 16 is in ohmic contact with contact region 18.

Next, a source wire 19 is formed. Source wire 19 is electrically connected to source electrode 16. Source wire 19 is formed so as to cover source electrode 16 and interlayer insulating film 26.

Next, a step of forming a drain electrode is performed. First, silicon carbide substrate 100 is polished on first main surface 1. Accordingly, the thickness of silicon carbide substrate 100 is reduced. Next, a drain electrode 24 is formed. Drain electrode 24 is formed so as to be in contact with silicon carbide substrate 100 on second main surface 2. In this way, silicon carbide semiconductor device 400 according to the embodiment is manufactured.

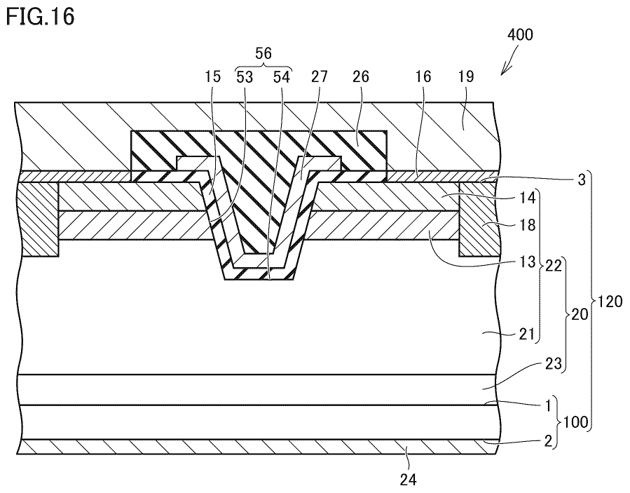

FIG. 16 is a schematic cross-sectional view showing a configuration of a silicon carbide semiconductor device according to the embodiment. Silicon carbide semiconductor device 400 is, for example, a MOSFET. Silicon carbide semiconductor device 400 mainly includes silicon carbide epitaxial substrate 120, gate electrode 27, gate insulating film 15, source electrode 16, drain electrode 24, source wire 19, and interlayer insulating film 26. Silicon carbide epitaxial substrate 120 includes drift region 21, body region 13, source region 14, and contact region 18. Silicon carbide semiconductor device 400 may be, for example, an insulated gate bipolar transistor (IGBT) or the like.

### (Function and Effect)

Next, the function and effect of the method of manufacturing silicon carbide substrate 100 and silicon carbide semiconductor device 400 according to the embodiment will be described.

When the carrier lifetime of silicon carbide substrate 100 is long, on-resistance of silicon carbide semiconductor device 400 is reduced. When the carrier lifetime of silicon carbide substrate 100 is short, switching performance of silicon carbide semiconductor device 400 is improved. That is, performance of silicon carbide semiconductor device 400 manufactured using silicon carbide substrate 100 depends on the carrier lifetime of silicon carbide substrate 100. Silicon carbide semiconductor devices 400 are manufactured from one silicon carbide substrate 100. Thus, as variation in carrier lifetimes in first main surface 1 of silicon carbide substrate 100 is smaller, variation in performance of silicon carbide semiconductor device 400 is smaller. However, even when silicon carbide substrate 100 having a small variation in carrier lifetimes is used, the variation in performance of silicon carbide semiconductor device 400 is larger than expected.

The inventors have paid attention to an activation annealing step, which is one of the manufacturing steps of silicon carbide semiconductor device 400, in the course of investigating the cause of the above phenomenon in detail. In the activation annealing step, silicon carbide substrate 100 is heated at, for example, about 1700° C. When silicon carbide substrate 100 is heated, the energy of carbon atom 12 of silicon carbide substrate 100 increases. Thus, carbon atoms 12 escape from the crystal lattice, and carbon vacancies 99 are generated.

A density of generated carbon vacancies 99 depends on the temperature of silicon carbide substrate 100. When the temperature of silicon carbide substrate 100 changes rapidly, a temperature difference occurs between the outer side and inner side of silicon carbide substrate 100. Thus, when silicon carbide substrate 100 is heated, variation in the density of carbon vacancies 99 in silicon carbide substrate 100 may be increased. In silicon carbide substrate 100, as variation in the density of carbon vacancies 99 increases, variation in the carrier lifetimes increases. Thus, even in silicon carbide substrate 100 having a small variation in carrier lifetime, it is considered that the variation in carrier lifetimes is increased by heating in the activation annealing step. Thus, it is considered that the variation in the performance of silicon carbide semiconductor devices 400 is larger than expected even when silicon carbide substrate 100 having a small variation in the carrier lifetimes is used.

It is considered that, when silicon carbide substrate 100 is cooled in a short time after the heating, the variation in carrier lifetimes is larger than that in the case where silicon carbide substrate 100 is gradually cooled. At a temperature of about 1000° C. or less, interstitial carbons 98 are unable to migrate in the crystal. Thus, when the cooling is performed in a short time, interstitial carbons 98 become unable to migrate before interstitial carbons 98 migrate and recombine with carbon vacancies 99. As a result, it is considered that the variation in the density of carbon vacancies 99 increased by the heating is maintained even after cooling in silicon carbide substrate 100. In the activation annealing step, silicon carbide substrate 100 is cooled for a short time after the heating. Thus, it is considered that the variation in the carrier lifetimes in silicon carbide substrate 100 is further increased by the activation annealing step.

The inventors have conducted intensive studies based on the results of the above investigation on the variation in performance of silicon carbide semiconductor device 400, and as a result, have found the method of manufacturing silicon carbide substrate 100 according to the embodiment. Specifically, the inventors have found that the change in the variation in the carrier lifetimes before and after the activation annealing step is reduced by heat-treating silicon carbide crystal 110 at the heat treatment temperature of 1900° C. to 2100° C. for 20 hours or more.

By performing the heat treatment on silicon carbide crystal 110 for a long time, interstitial carbons 98 decrease and carbon vacancies 99 increase in silicon carbide substrate 100. Since there are many carbon vacancies 99, when silicon carbide substrate 100 is heated again to a temperature equal to or less than the heat treatment temperature, neither carbon vacancies 99 nor interstitial carbons 98 are generated. Thus, interstitial carbons 98 are maintained in a small amount. Since interstitial carbons 98 are in a small amount, recombination of interstitial carbons 98 and carbon vacancies 99 does not occur when silicon carbide substrate 100 is cooled. Thus, each of interstitial carbons 98 and carbon vacancies 99 do not decrease. Thus, it is considered that the heat treatment of silicon carbide crystal 110 suppresses the change in the density of each of carbon vacancies 99 and interstitial carbons 98. As a result, it is considered that the change in the variation in the carrier lifetimes of silicon carbide substrate 100 before and after the activation annealing step is reduced.

Further, by performing the heat treatment at a high temperature for a long time, silicon carbide crystal 110 is in a state of a high temperature and high temperature uniformity. Thus, in silicon carbide crystal 110, the density of interstitial carbons 98 can be significantly reduced while maintaining a state where the density of each of interstitial carbons 98 and carbon vacancies 99 is highly uniform. Thus, even when the temperature of silicon carbide crystal 110 is lowered, the density of each of interstitial carbons 98 and carbon vacancies 99 is maintained in the highly uniform state. As a result, silicon carbide substrate 100 having a small variation in carrier lifetimes is obtained.

Based on the above findings, the inventors have conceived that the change in the variation in carrier lifetimes before and after the activation annealing step can be reduced by performing heat treatment on silicon carbide crystal 110 at a temperature of 1900° C. to 2100° C. for 20 hours or more.

It is considered that the effect of the method of manufacturing according to the embodiment can be similarly obtained in a heating step other than the activation annealing step. Specifically, it is considered that the effect of reducing the change in the variation in the carrier lifetimes can be obtained also before and after the step of forming the epitaxial layer in the method of manufacturing silicon carbide semiconductor device 400, for example.

According to silicon carbide substrate 100 of the embodiment, when a standard deviation of the carrier lifetimes in central region 5 before a process of heating to a temperature of 1600° C. to 1900° C. is performed is defined as a first standard deviation and a standard deviation of the carrier lifetimes in central region 5 after the process is performed is defined as a second standard deviation, a value obtained by subtracting the first standard deviation from the second standard deviation is 10% or less of the first standard deviation. Thus, the yield of silicon carbide semiconductor device 400 manufactured using silicon carbide substrate 100 can be improved.

Further, according to silicon carbide substrate 100 of the embodiment, the first standard deviation is 0.7 ns or less. Thus, the yield of silicon carbide semiconductor device 400 can be further improved.

Further, according to silicon carbide substrate 100 of the embodiment, the value obtained by subtracting the first standard deviation from the second standard deviation may be 5% or less of the first standard deviation. This can further improve the yield of silicon carbide semiconductor device 400.

Furthermore, according to silicon carbide substrate 100 of the embodiment, an average value of the carrier lifetimes in the central region is 200 ns or less. This improves the switching performance of silicon carbide semiconductor device 400.

According to silicon carbide substrate 100 of the embodiment, first main surface 1 has a diameter of 100 mm or more. Thus, the yield of silicon carbide semiconductor device 400 can be improved even in silicon carbide substrate 100 having a large diameter.

According to the method of manufacturing silicon carbide substrate 100 of the embodiment, silicon carbide crystal 110 is heat-treated at the heat treatment temperature for 20 hours or more. The heat treatment temperature is 1900° C. or more. Thus, in the process of manufacturing silicon carbide semiconductor device 400, even when the process of heating silicon carbide substrate 100 to a temperature of 1600° C. to 1900° C. is performed, a change in the standard deviation of the carrier lifetimes of silicon carbide substrate 100 can be reduced. As a result, the yield of silicon carbide semiconductor device 400 can be improved.

According to the method of manufacturing silicon carbide substrate 100 of the embodiment, silicon carbide crystal 110 is heat-treated at the heat treatment temperature for 20 hours or more. The heat treatment temperature is 2100° C. or less. When the heat treatment temperature is more than 2100° C., the density of carbon vacancies 99 of silicon carbide substrate 100 becomes higher than necessary. Carbon vacancies 99 trap majority carriers of silicon carbide substrate 100. Accordingly, the electrical resistivity of silicon carbide substrate 100 increases. Thus, by setting the heat treatment temperature to be 2100° C. or less, increase in the electrical resistivity of silicon carbide substrate 100 can be suppressed.

According to the method of manufacturing silicon carbide semiconductor device 400 of the embodiment, in the step of forming the silicon carbide epitaxial layer, silicon carbide substrate 100 is heated to the temperature of 1600° C. to 1800° C. The temperature of the activation annealing is 1500° C. to 1850° C. Thus, even when silicon carbide substrate 100 is heated, the yield loss of silicon carbide semiconductor device 400 can be reduced.

### EXAMPLE

Next, a test using samples will be described. First, silicon carbide substrates 100 of sample 1 and sample 2 were prepared. Sample 1 was a comparative example. Sample 2 was an example. Sample 1 and sample 2 were produced using the method of manufacturing according to the embodiment described above. In manufacturing silicon carbide substrate 100 of Sample 1, the heat treatment step (S20) was not performed. In manufacturing silicon carbide substrate 100 of sample 2, the heat treatment temperature was 2000° C. The heat treatment time was 20 hours. Argon gas was used as the atmospheric gas in crucible 30 in the heat treatment step (S20). The pressure inside crucible 30 was set to 80 kPa. In the heat treatment step (S20), silicon carbide substrate 100 was cooled to 1000° C. or less in 5 hours after the heat treatment. The diameter of silicon carbide substrate 100 was set to 150 mm.

### (Measurement Method)

In all the samples, the standard deviation of the carrier lifetimes was measured. Specifically, in all the samples, the standard deviation (first standard deviation) of the carrier lifetimes was measured after silicon carbide substrate 100 was manufactured. Then, the sample was placed in crucible 30, and the process of heating was performed at 1700° C. for 30 minutes. During the process of heating, the pressure in crucible 30 was about 80 kPa. The heated silicon carbide substrate 100 was cooled to 1000° C. or less in 30 minutes. The sample was taken out from crucible 30, and the standard deviation (second standard deviation) of the carrier lifetimes was measured. Thereafter, the sample was placed again in crucible 30, and the process of heating was performed at 1850° C. for 30 minutes. The heated silicon carbide substrate 100 was cooled to 1000° C. or less in 30 minutes. The sample was taken out from crucible 30, and the standard deviation of the carrier lifetimes (hereinafter referred to as the third standard deviation) was measured. A value obtained by dividing the difference between the second standard deviation and the first standard deviation by the first standard deviation is referred to as a rate of change in the standard deviation due to heating at 1700° C. A value obtained by dividing the difference between the third standard deviation and the first standard deviation by the first standard deviation is referred to as a rate of change in the standard deviation due to heating at 1850° C.

In measuring the carrier lifetimes, a lifetime measurement apparatus LTA-2200EP manufactured by Kobelco Research Institute was used. The probe frequency was 26 GHz. The laser used was a YLF laser. The dopant of the YLF laser was neodymium. The pulse width of the laser was 5 ns. The laser wave length was 349 nm (third harmonic). The temperature at the time of measurement was room temperature. Distance D between adjacent measurement points 42 was set to be 2 mm. The number of measurement points 42 was 4200.

### (Measurement Results)

TABLE 1

| | First | Second | Third | Rate of Change of | Rate of Change of |
|---|---|---|---|---|---|
| | Standard | Standard | Standard | Standard Deviation due | Standard Deviation due |
| | Deviation | Deviation | Deviation | to Heating at 1700° C. | to Heating at 1850° C. |
| No. | S1 | S2 | S3 | (S2 − S1)/S1 × 100 | (S3 − S1)/S1 × 100 |
| Sample 1 | 0.7 ns | 0.78 ns | 0.88 ns | 11% | 26% |
| Sample 2 | 0.6 ns | 0.61 ns | 0.61 ns | 2% | 2% |

In sample 1 and sample 2, when the rates of change in the standard deviations due to heating at 1700° C. were compared, it was found that the rate of change in standard deviation of the carrier lifetimes before and after the process of heating to 1700° C. was performed was 10% or less in the case where the heat treatment step (S20) was performed. Further, when the rates of change in the standard deviations due to heating at 1850° C. were compared, it was found that the rate of change in the standard deviation of the carrier lifetimes before and after the process of heating to 1850° C. was performed was 10% or less in the case where the heat treatment step (S20) was performed.

It was confirmed that the heat treatment is preferably performed at a temperature of 1900° C. to 2100° C. for 20 hours or more in order to improve the yield of silicon carbide semiconductor device 400.

The embodiments disclosed herein are illustrative in all respects and should not be construed as limiting. The scope of the present invention is defined by the appended claims rather than the embodiments described above, and is intended to include all modifications within the scope and meaning equivalent to the appended claims.

### REFERENCE SIGNS LIST

1 first main surface, 2 second main surface, 3 third main surface, 4 outer peripheral region, 5 central region, 6 outer edge, 7 orientation flat portion, 8 arc-shaped portion, 9 first outer peripheral side surface, 11 silicon atom, 12 carbon atom, 13 body region, 14 source region, 15 gate insulating film, 16 source electrode, 17 mask, 18 contact region, 19 source wire, 20 silicon carbide epitaxial layer, 21 drift region, 22 drift layer, 23 buffer layer, 24 drain electrode, 26 interlayer insulating film, 27 gate electrode, 30 crucible, 31 lid portion, 32 container portion, 42 measurement point, 53 side wall surface, 54 bottom wall surface, 56 trench, 65 heat insulating member, 66 first through hole, 67 second through hole, 68 tubular portion, 69 bottom portion, 71 base portion, 72 holding portion, 73 top surface, 74 inner surface, 75 holding surface, 76 second outer peripheral side surface, 77 mounting surface, 78 bottom surface, 80 seed crystal, 81 source material powder, 82 attachment surface, 83 growth surface, 84 third outer peripheral side surface, 91 first radiation thermometer, 92 second radiation thermometer, 97 induction heating coil, 98 interstitial carbon, 99 carbon vacancy, 100 silicon carbide substrate, 101 first direction, 102 second direction, 103 third direction, 110 silicon carbide crystal, 120 silicon carbide epitaxial substrate, 200 manufacturing apparatus, 400 silicon carbide semiconductor device, D distance, E thickness, W1 first diameter, W2 second diameter, W3 third diameter, θ off-angle.

1. A silicon carbide substrate comprising a main surface,
wherein the main surface is constituted of an outer peripheral region that is a region within 5 mm from an outer edge of the main surface and a central region surrounded by the outer peripheral region,
a standard deviation of lifetimes of minority carriers in the central region is 0.7 ns or less, and
when a standard deviation of lifetimes of the minority carriers in the central region before a process of heating to a temperature of 1600° C. to 1900° C. is performed is defined as a first standard deviation and a standard deviation of lifetimes of the minority carriers in the central region after the process is performed is defined as a second standard deviation,
a value obtained by subtracting the first standard deviation from the second standard deviation is 10% or less of the first standard deviation.

2. The silicon carbide substrate according to claim 1, wherein a concentration of majority carriers in the central region is 1×10⁷ cm⁻³ or more.

3. The silicon carbide substrate according to claim 2, wherein the majority carriers are n-type carriers.

4. The silicon carbide substrate according to claim 1, wherein the value obtained by subtracting the first standard deviation from the second standard deviation is 5% or less of the first standard deviation.

5. The silicon carbide substrate according to claim 1, wherein an average value of the lifetimes of the minority carriers in the central region is 200 ns or less.

6. The silicon carbide substrate according to claim 1, wherein the main surface has a diameter of 100 mm or more.

7. The silicon carbide substrate according to claim 1, wherein the main surface is inclined at an off-angle in an off-direction relative to a {0001}plane, and
the off-angle is more than 0° and 8° or less.

8. A method of manufacturing a silicon carbide semiconductor device, the method comprising:
preparing the silicon carbide substrate according to claim 1; and
processing the silicon carbide substrate.

9. A method of manufacturing a silicon carbide substrate, the method comprising:
growing a silicon carbide crystal on a seed crystal by sublimating source material powder in which carbon powder is added to silicon carbide powder; and
performing heat treatment on the grown silicon carbide crystal,
wherein in the performing heat treatment,
a heat treatment temperature is 1900° C. to 2100° C., and
a heat treatment time is 20 hours or more.
